(19) United States
(12) Patent Application Publication
(10) Pub. No.: US 2025/0102559 A1
(43) Pub. Date: Mar. 27, 2025

(54) CHIP ELECTRICAL PROPERTY DETECTION DEVICE AND METHOD OF MANUFACTURING THE SAME

(71) Applicant: ASTI GLOBAL INC., TAIWAN, Taichung City (TW)

(72) Inventor: CHIEN-SHOU LIAO, Taichung City (TW)

(21) Appl. No.: 18/806,672

(22) Filed: Aug. 15, 2024

Related U.S. Application Data
(60) Provisional application No. 63/540,638, filed on Sep. 26, 2023.

(51) Int. Cl. G01R 31/26; G01R 31/28

(52) U.S. Cl. CPC G01R 31/2635; G01R 31/2884; G01R 31/2893

(57) ABSTRACT

A chip electrical property detection device and a method of manufacturing the same are provided. The chip electrical property detection device includes a circuit control module and an electrical detection module. The circuit control module includes a flexible circuit substrate and multiple electrical conduction structures. The electrical detection module includes multiple movable carrying substrates, multiple electrical detection structures and multiple electrical connection structures. The movable carrying substrates are separate from each other and arranged on the flexible circuit substrate. The electrical detection structures are respectively disposed on the movable carrying substrates and electrically connected to the electrical connection structures. The electrical connection structures penetrate the movable carrying substrates and electrically connect to the electrical conduction structures, respectively. Each movable carrying substrate is allowed to be slightly adjusted through the flexible circuit substrate, thereby allowing each electrical detection structure to be slightly adjusted following the corresponding movable carrying substrate.

### CROSS-REFERENCE TO RELATED PATENT APPLICATION

This application claims the benefit of priority to the U.S. Provisional Patent Application Ser. No. 63/540,638, filed on Sep. 26, 2023, which application is incorporated herein by reference in its entirety.

Some references, which may include patents, patent applications and various publications, may be cited and discussed in the description of this disclosure. The citation and/or discussion of such references is provided merely to clarify the description of the present disclosure and is not an admission that any such reference is “prior art” to the disclosure described herein. All references cited and discussed in this specification are incorporated herein by reference in their entireties and to the same extent as if each reference was individually incorporated by reference.

### FIELD OF THE DISCLOSURE

The present disclosure relates to a detection device and a method of manufacturing the same, and more particularly to a chip electrical property detection device and a method of manufacturing the same.

### BACKGROUND OF THE DISCLOSURE

In the related art, during the lighting test of wafer-level micro LED chips or mini LED chips, multiple LED chips will be sequentially tested and screened one by one through the power supply of the probe detection device, but the testing and screening speed is quite slow. If multiple probe detection devices are used to supplement the testing speed, the production cost will be increased and the overall production efficiency will be very low.

### SUMMARY OF THE DISCLOSURE

In response to the above-referenced technical inadequacy, the present disclosure provides a chip electrical property detection device and a method of manufacturing the same.

In order to solve the above-mentioned problems, one of the technical aspects adopted by the present disclosure is to provide a chip electrical property detection device, which includes a circuit control module and an electrical detection module. The circuit control module includes a flexible circuit substrate and a plurality of electrical conduction structures. The electrical detection module includes a plurality of movable carrying substrates, a plurality of electrical detection structures and a plurality of electrical connection structures. The circuit control module and the electrical detection module are configured to cooperate with each other to form the chip electrical property detection device. The flexible circuit substrate has a predetermined circuit layout, and the electrical conduction structures are disposed on the flexible circuit substrate and electrically connected to the predetermined circuit layout of the flexible circuit substrate. The movable carrying substrates are separate from each other and disposed on the flexible circuit substrate, the electrical detection structures are respectively disposed on the movable carrying substrates and electrically connected to the electrical connection structures, and the electrical connection structures respectively pass through the movable carrying substrates and are respectively and electrically connected to the electrical conduction structures.

In order to solve the above-mentioned problems, another one of the technical aspects adopted by the present disclosure is to provide a method of manufacturing a chip electrical property detection device, which includes: providing a circuit control module, in which the circuit control module includes a flexible circuit substrate and a plurality of electrical conduction structures; providing an electrical detection module, in which the electrical detection module includes a plurality of movable carrying substrates, a plurality of electrical detection structures and a plurality of electrical connection structures; and cooperating the circuit control module and the electrical detection module with each other to form the chip electrical property detection device. The flexible circuit substrate has a predetermined circuit layout, and the electrical conduction structures are disposed on the flexible circuit substrate and electrically connected to the predetermined circuit layout of the flexible circuit substrate. The movable carrying substrates are separate from each other and disposed on the flexible circuit substrate, the electrical detection structures are respectively disposed on the movable carrying substrates and electrically connected to the electrical connection structures, and the electrical connection structures respectively pass through the movable carrying substrates and are respectively and electrically connected to the electrical conduction structures.

Therefore, in the chip electrical property detection device provided by the present disclosure, by virtue of “the circuit control module including a flexible circuit substrate and a plurality of electrical conduction structures,” “the electrical detection module including a plurality of movable carrying substrates, a plurality of electrical detection structures and a plurality of electrical connection structures,” “the movable carrying substrates being separate from each other and disposed on the flexible circuit substrate,” “the electrical detection structures being respectively disposed on the movable carrying substrates and electrically connected to the electrical connection structures” and “the electrical connection structures respectively passing through the movable carrying substrates and respectively and electrically connecting to the electrical conduction structures,” each of the movable carrying substrates can be configured to be allowed to be slightly adjusted through the flexible circuit substrate, thereby allowing each of the electrical detection structures to be configured to be slightly adjusted following the corresponding movable carrying substrate.

Furthermore, in the method of manufacturing the chip electrical property detection device provided by the present disclosure, by virtue of “providing a circuit control module, in which the circuit control module includes a flexible circuit substrate and a plurality of electrical conduction structures,” “providing an electrical detection module, in which the electrical detection module includes a plurality of movable carrying substrates, a plurality of electrical detection structures and a plurality of electrical connection structures,” “cooperating the circuit control module and the electrical detection module with each other to form the chip electrical property detection device,” “the movable carrying substrates being separate from each other and disposed on the flexible circuit substrate,” “the electrical detection structures being respectively disposed on the movable carrying substrates and electrically connected to the electrical connection structures” and “the electrical connection structures respectively passing through the movable carrying substrates and respectively and electrically connecting to the electrical conduction structures,” each of the movable carrying substrates can be configured to be allowed to be slightly adjusted through the flexible circuit substrate, thereby allowing each of the electrical detection structures to be configured to be slightly adjusted following the corresponding movable carrying substrate.

These and other aspects of the present disclosure will become apparent from the following description of the embodiment taken in conjunction with the following drawings and their captions, although variations and modifications therein may be affected without departing from the spirit and scope of the novel concepts of the disclosure.

### BRIEF DESCRIPTION OF THE DRAWINGS

The described embodiments may be better understood by reference to the following description and the accompanying drawings, in which:

FIG. 1 is a flowchart of a method for manufacturing a chip electrical property detection device according to a first embodiment of the present disclosure;

FIG. 2 is a schematic view of a circuit control module of the chip electrical property detection device provided by the first embodiment of the present disclosure;

FIG. 3 is a schematic view of an electrical detection module of the chip electrical property detection device provided by the first embodiment of the present disclosure;

FIG. 4 is a schematic view of the mutual cooperation structure between the circuit control module and the electrical detection module of the chip electrical property detection device provided by the first embodiment of the present disclosure (before separating the movable carrying substrates from each other);

FIG. 5 is a schematic view of the mutual cooperation structure between the circuit control module and the electrical detection module of the chip electrical property detection device provided by the first embodiment of the present disclosure (after separating the movable carrying substrates from each other);

FIG. 6 is a schematic view of the chip electrical property detection device configured to be applied to detect multiple chips to be detected according to the first embodiment of the present disclosure (before downward pressing the chip electrical property detection device to detect the multiple chips to be detected through a downward pressure provided by a flexible pressing device);

FIG. 7 is a schematic view of the chip electrical property detection device configured to be applied to detect the multiple chips to be detected according to the first embodiment of the present disclosure (when downward pressing the chip electrical property detection device to detect the multiple chips to be detected through the downward pressure provided by the flexible pressing device);

FIG. 8 is a schematic view of the electrical detection module of the chip electrical property detection device provided by a second embodiment of the present disclosure;

FIG. 9 is a schematic view of the mutual cooperation structure between the circuit control module and the electrical detection module of the chip electrical property detection device provided by the second embodiment of the present disclosure (before separating the movable carrying substrates from each other);

FIG. 10 is a schematic view of the mutual cooperation structure between the circuit control module and the electrical detection module of the chip electrical property detection device provided by the second embodiment of the present disclosure (after separating the movable carrying substrates from each other);

FIG. 11 is a schematic view of the mutual cooperation structure between the circuit control module and the electrical detection module of the chip electrical property detection device provided by a third embodiment of the present disclosure; and

FIG. 12 is a schematic view of the mutual cooperation structure between the circuit control module and the electrical detection module of the chip electrical property detection device provided by a fourth embodiment of the present disclosure.

### DETAILED DESCRIPTION OF THE EXEMPLARY EMBODIMENTS

The present disclosure is more particularly described in the following embodiments and examples that are intended as illustrative only since numerous modifications and variations therein will be apparent to those skilled in the art. Like numbers in the drawings indicate like components throughout the views. As used in the description herein and throughout the claims that follow, unless the context clearly dictates otherwise, the meaning of “a,” “an” and “the” includes plural reference, and the meaning of “in” includes “in” and “on.” Titles or subtitles can be used herein for the convenience of a reader, which shall have no influence on the scope of the present disclosure.

The terms used herein generally have their ordinary meanings in the art. In the case of conflict, the present document, including any definitions given herein, will prevail. The same thing can be expressed in more than one way. Alternative language and synonyms can be used for any term(s) discussed herein, and no special significance is to be placed upon whether a term is elaborated or discussed herein. A recital of one or more synonyms does not exclude the use of other synonyms. The use of examples anywhere in this specification including examples of any terms is illustrative only, and in no way limits the scope and meaning of the present disclosure or of any exemplified term. Likewise, the present disclosure is not limited to various embodiments given herein. Numbering terms such as “first,” “second” or “third” can be used to describe various components, signals or the like, which are for distinguishing one component/signal from another one only, and are not intended to, nor should be construed to impose any substantive limitations on the components, signals or the like.

### First Embodiment

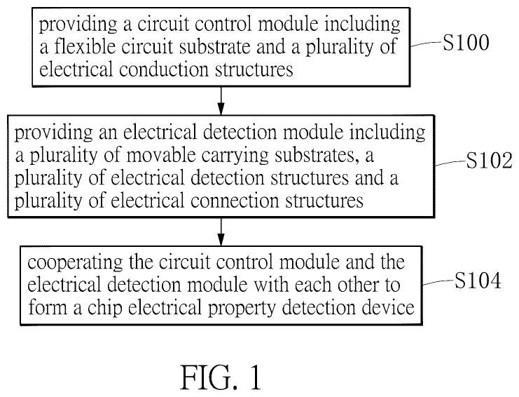

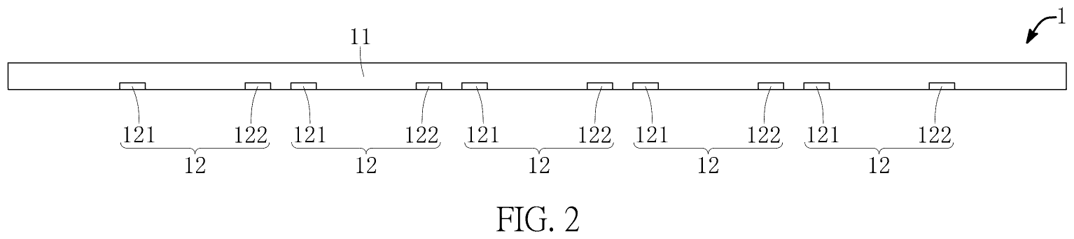

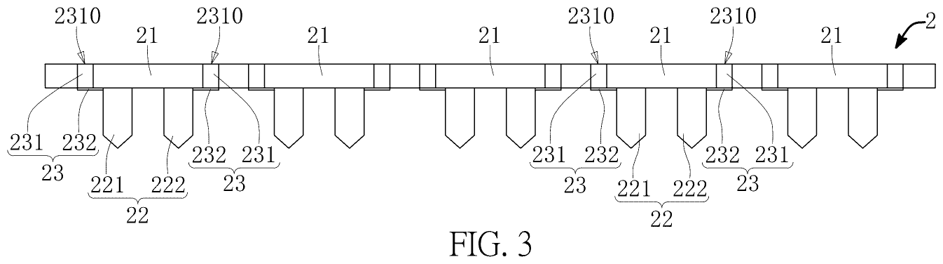

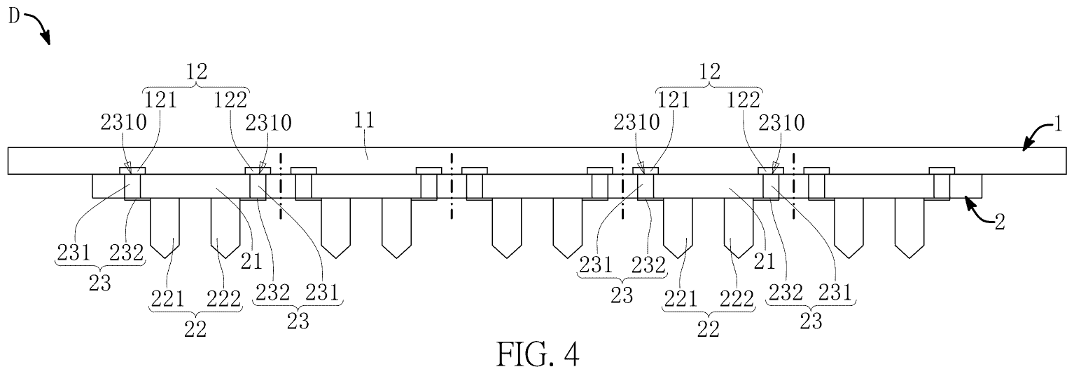

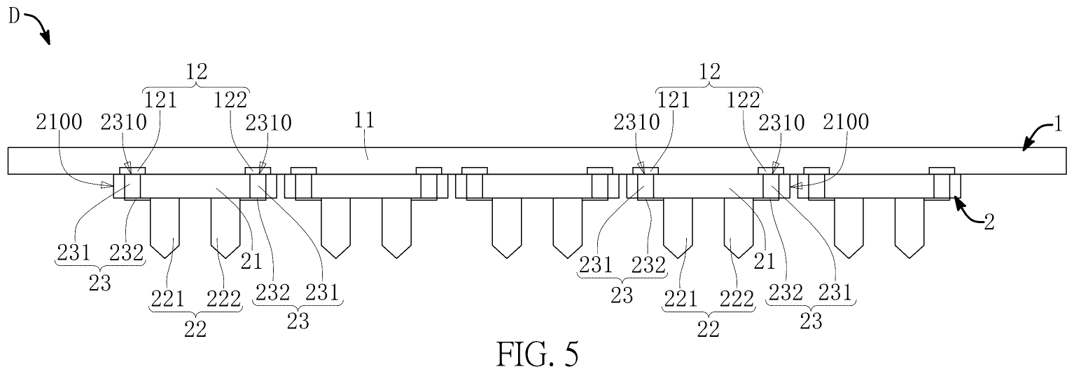

Referring to FIG. 1 to FIG. 7, a first embodiment of the present disclosure provides a method of manufacturing a chip electrical property detection device D, which may at least include: firstly, referring to FIG. 1 and FIG. 2, providing a circuit control module 1, in which the circuit control module 1 includes a flexible circuit substrate 11 and a plurality of electrical conduction structures 12 (step S100); next, referring to FIG. 1 and FIG. 3, providing an electrical detection module 2, in which the electrical detection module 2 includes a plurality of movable carrying substrates 21 (before the movable carrying substrates 21 can be separated from each other), a plurality of electrical detection structures 22 and a plurality of electrical connection structures 23 (step S102); then, referring to FIG. 1 and FIG. 4, cooperating (or matching) the circuit control module 1 and the electrical detection module 2 with each other (such as electrically bonding the circuit control module 1 on the electrical detection module 2) to form the chip electrical property detection device D (step S104). It should be noted that referring to FIG. 4 and FIG. 5, in the step S104, the electrical detection module 2 can perform a cutting step (or a material removal step) along the multiple cutting lines (i.e., multiple imaginary lines as shown in FIG. 4), so that the movable carrying substrates 21 can be separated from each other and can move independently. For example, when the movable carrying substrates 21 are separated from each other through the cutting step (or the material removal step), two adjacent ones of the movable carrying substrates 21 can be separated from each other by a predetermined distance, and an outer surrounding surface of each movable carrying substrate 21 can be a surrounding cutting surface 2100 (or a surrounding roughened surface) formed by cutting or removing material. However, the aforementioned details are disclosed for exemplary purposes only, and are not meant to limit the scope of the present disclosure.

Moreover, as shown in FIG. 2, the flexible circuit substrate 11 has a predetermined circuit layout (or a predetermined circuit pattern including multiple conductive vias, or a predetermined circuit trace including multiple conductive vias, or an LED lighting circuit including multiple scan lines and multiple data lines that can be manufactured by a semiconductor process), and the electrical conduction structures 12 (or the electrically conductive pads) can be disposed on the flexible circuit substrate 11 and electrically connected to the predetermined circuit layout of the flexible circuit substrate 11. For example, in one of the feasible embodiments, the predetermined circuit layout of the flexible circuit substrate 11 may include one or more bottom circuits (not shown) provided on the bottom side of the flexible circuit substrate 11, one or more top circuit (not shown) provided on the top side of the flexible circuit substrate 11, and one or more through circuits (or conductive vias, not shown) penetrating the flexible circuit substrate 11, and the flexible circuit substrate 11 can be configured as a polyimide (PI) flexible circuit board, a modified polyimide (MPI) flexible circuit board, a polyester (PET) flexible circuit board, a liquid crystal polymer (LCP) flexible circuit board or any kind of flexible circuit substrate that can use any kind of polymer film material. In addition, each electrical conduction structure 12 of the circuit control module 1 may at least include a first conduction contact 121 (or a first conductive soldering area) and a second conduction contact 122 (or a second conductive soldering area) adjacent to each other, and the first conduction contact 121 and the second conduction contact 122 of each electrical conduction structure 12 can be electrically connected to the bottom circuit (not shown) or the through circuit (not shown) of the flexible circuit substrate 11. However, the aforementioned details are disclosed for exemplary purposes only, and are not meant to limit the scope of the present disclosure.

More particularly, referring to FIG. 3, FIG. 4 and FIG. 5, the movable carrying substrates 21 can be separated from each other and disposed on the flexible circuit substrate 11 by cutting or removing material (or by a cutting step or a material removal step), the electrical detection structures 22 can be respectively disposed on the movable carrying substrates 21 and electrically connected to the electrical connection structures 23, and the electrical connection structures 23 can respectively pass through the movable carrying substrates 21 and can be respectively and electrically connected to the electrical conduction structures 12. For example, in one of the feasible embodiments, the movable carrying substrate 21 can be configured as a silicon wafer substrate or any kind of relatively rigid carrier substrate, each electrical detection structure 22 may at least include a first electrical detection probe 221 (or a first power supply probe, or a first electrical contact probe, or a P-pole contact probe) and a second electrical detection probe 222 (or a second power supply probe, or a second electrical contact probe, or an N-pole contact probe), and each electrical connection structure 23 may at least include two conductive through layers 231 or two conductive penetrating layers (such as two solid conductive pillars, two hollow conductive vias or two through-silicon vias (TSV)) and two conductive connection layers 232 (such as two conductive circuit layers). More particularly, the two conductive through layers 231 can pass through a corresponding one of the movable carrying substrates 21, and the two conductive connection layers 232 can be disposed on a bottom side of the corresponding movable carrying substrate 21, each conductive through layer 231 has a top conductive contact 2310 (or a top conductive soldering area) disposed on a top side thereof, and a bottom side of each conductive through layer 231 can be directly electrically connected to or in electrical contact with one of the conductive connection layers 232. Therefore, as shown in FIG. 5, when the circuit control module 1 and the electrical detection module 2 cooperate with each other to form the chip electrical property detection device D, the first electrical detection probe 221 can be electrically connected to the circuit control module 1 through a corresponding one of the conductive connection layers 232, a corresponding one of the conductive through layers 231, and a corresponding one of the first conduction contacts 121 in sequence, and the second electrical detection probe 222 can be electrically connected to the circuit control module 1 through another corresponding one of the conductive connection layers 232, another corresponding one of the conductive through layers 231 and another corresponding one of the second conduction contacts 122 in sequence. However, the aforementioned details are disclosed for exemplary purposes only, and are not meant to limit the scope of the present disclosure.

It should be noted that as shown in FIG. 5, the movable carrying substrates 21 can be separately disposed on a bottom side of the flexible circuit substrate 11 by cutting or removing material, so that each movable carrying substrate 21 can be configured to be allowed to be slightly adjusted through the flexible bearing of the flexible circuit substrate 11 (that is to say, the position of each movable carrying substrate 21 can be allowed to be slightly adjusted through the soft carrier or flexible carrier of the flexible circuit substrate 11, the flexible circuit substrate 11 can be used as a flexible carrier shared by the multiple movable carrying substrates 21, and each movable carrying substrate 21 can be slightly adjusted or moved in a horizontal direction, a vertical direction or a tilt direction), thereby allowing each electrical detection structure 22 to be configured to be slightly adjusted following the corresponding movable carrying substrate 21 (that is to say, each electrical detection structure 22 can be configured to be in a state that the position can be slightly adjusted corresponding to the corresponding movable carrying substrate 21). For example, the first electrical detection probe 221 and the second electrical detection probe 222 of each electrical detection structure 22 can be slightly adjusted or moved in the horizontal direction, the vertical direction or the tilt direction at the same time). However, the aforementioned details are disclosed for exemplary purposes only, and are not meant to limit the scope of the present disclosure.

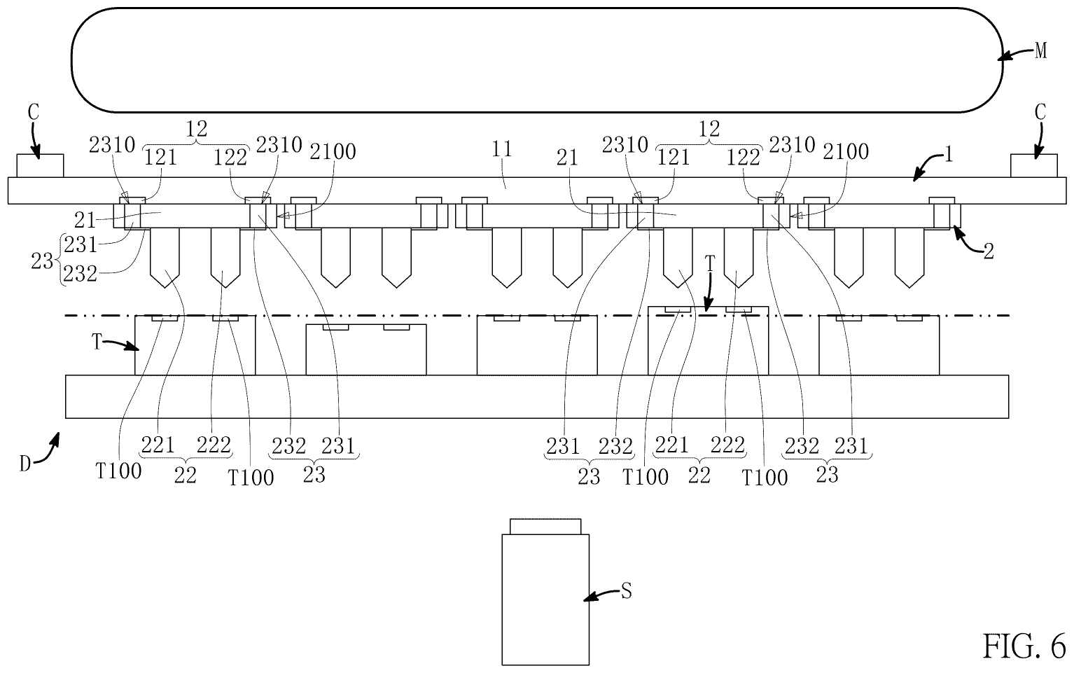

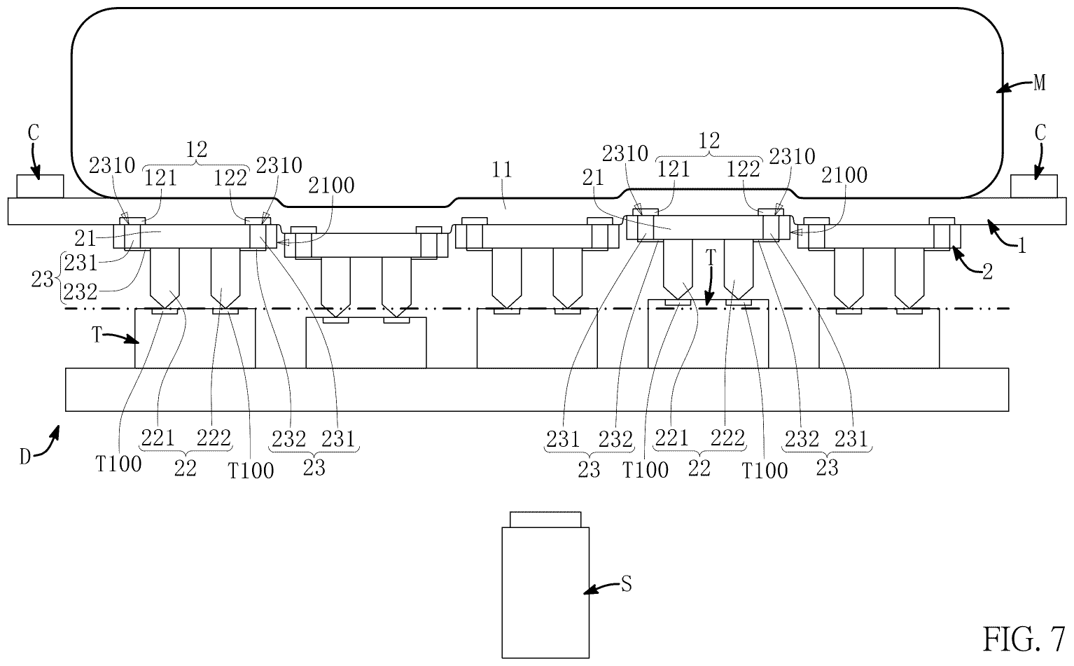

For example, referring to FIG. 6 and FIG. 7, when the chip electrical property detection device D (such as an LED lighting and testing instrument) can be configured to detect a plurality of chips T to be detected (such as multiple micro LED dies or multiple mini LED dies disposed on a gallium arsenide epitaxial wafer, or any kind of unpackaged light-emitting die), the chip electrical property detection device D can be configured to be moved downward through a downward pressure provided by a flexible pressing device (such as an air bag or any kind of flexible pressing plate as shown in FIG. 7), so that the first electrical detection probe 221 and the second electrical detection probe 222 of each electrical detection structure 22 can reliably electrically contact two conductive pads T100 of a corresponding one of the chips T to be detected respectively, or the first electrical detection probe 221 and the second electrical detection probe 222 of each electrical detection structure 22 can provide a fixed current (or a fixed voltage) to the two conductive pads T100 of the corresponding chip T to be detected. It should be noted that as shown in FIG. 7, even when the plurality of chips T to be detected are not in a completely flat state such that the plurality of conductive pads T100 of the plurality of chips T to be detected cannot be located on the same horizontal plane (as shown by the imaginary line in FIG. 7), each electrical detection structure 22 can be configured to allow its position to be slightly adjusted following the corresponding movable carrying substrate 21, so that the first electrical detection probe 221 and the second electrical detection probe 222 of each electrical detection structure 22 can reliably electrically contact the two conductive pads T100 of the corresponding chip T to be detected, or the first electrical detection probe 221 and the second electrical detection probe 222 of each electrical detection structure 22 can reliably provide a fixed current (or a fixed voltage) to the two conductive pads T100 of the corresponding chip T to be detected. Therefore, the multiple chips T to be detected can generate detection light sources through the electrical supply of the multiple electrical detection structures 22 at the same time, thereby providing the detection light source to the optical detection device S to facilitate relevant optical detection (or LED lighting test) of multiple chips T to be detected. However, the aforementioned details are disclosed for exemplary purposes only, and are not meant to limit the scope of the present disclosure.

It should be noted that, for example, as shown in FIG. 6 or FIG. 7, the flexible circuit substrate 11 of the circuit control module 1 can be configured to carry a plurality of functional chips C (such as control chips, memory chips or any kind of semiconductor chips), and each functional chip C can be electrically connected to a corresponding one of the electrical detection structures 22 through a corresponding one of the electrical conduction structures 12 and a corresponding one of the electrical connection structures 23. However, the aforementioned details are disclosed for exemplary purposes only, and are not meant to limit the scope of the present disclosure.

More particularly, referring to FIG. 5, FIG. 6 and FIG. 7, the first embodiment of the present disclosure further provides a chip electrical property detection device D (or a chip electrical status testing device), which includes a circuit control module 1 and an electrical detection module 2, and the circuit control module 1 and the electrical detection module 2 can be configured to cooperate with each other in any way to form the chip electrical property detection device D. Moreover, the circuit control module 1 includes a flexible circuit substrate 11 and a plurality of electrical conduction structures 12, in which the flexible circuit substrate 11 has a predetermined circuit layout, and the electrical conduction structures 12 can be disposed on the flexible circuit substrate 11 and electrically connected to the predetermined circuit layout of the flexible circuit substrate 11. In addition, the electrical detection module 2 includes a plurality of movable carrying substrates 21, a plurality of electrical detection structures 22 and a plurality of electrical connection structures 23, in which the movable carrying substrates 21 can be separated from each other and disposed on the flexible circuit substrate 11, the electrical detection structures 22 can be respectively disposed on the movable carrying substrates 21 and electrically connected to the electrical connection structures 23, and the electrical connection structures 23 can respectively pass through the movable carrying substrates 21 and can be respectively and electrically connected to the electrical conduction structures 12. For example, the movable carrying substrates 21 can be separately disposed on a bottom side of the flexible circuit substrate 11 by cutting or removing material, so that each movable carrying substrate 21 can be configured to be allowed to be slightly adjusted through the flexible bearing of the flexible circuit substrate 11, thereby allowing each electrical detection structure 22 to be configured to be slightly adjusted following the corresponding movable carrying substrate 21. Furthermore, as shown in FIG. 7, each electrical detection structure 22 can be configured to be slightly adjusted following the corresponding movable carrying substrate 21, so that the first electrical detection probe 221 and the second electrical detection probe 222 of each electrical detection structure 22 can reliably electrically contact two conductive pads T100 of a corresponding one of the chips T to be detected respectively, or the first electrical detection probe 221 and the second electrical detection probe 222 of each electrical detection structure 22 can provide a fixed current (or a fixed voltage) to the two conductive pads T100 of the corresponding chip T to be detected. However, the aforementioned details are disclosed for exemplary purposes only, and are not meant to limit the scope of the present disclosure.

### Second Embodiment

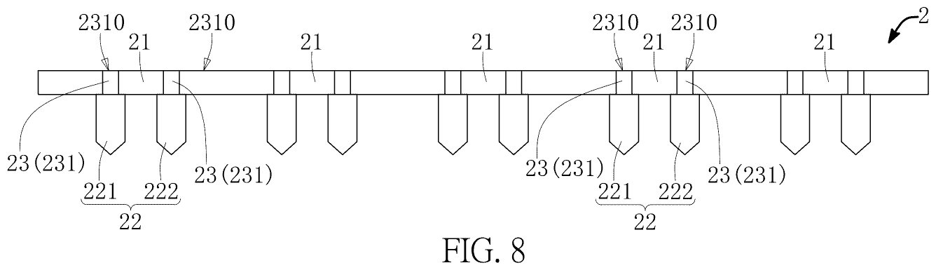

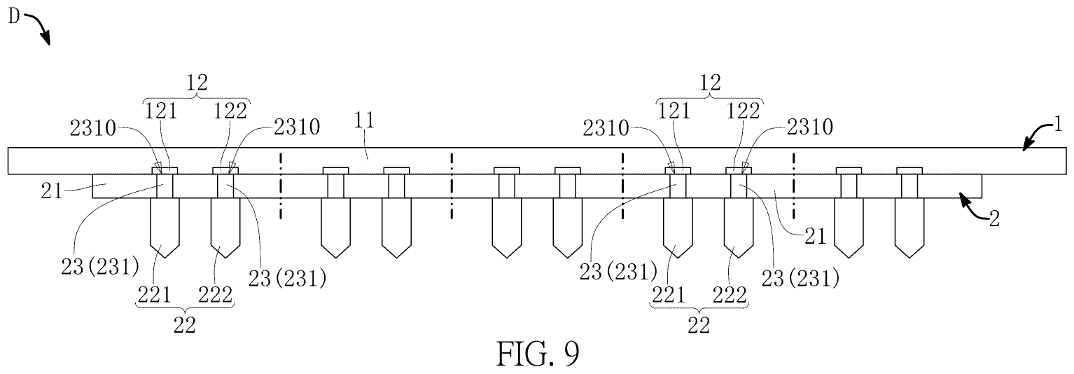

Referring to FIG. 8 to FIG. 10, a second embodiment of the present disclosure provides a chip electrical property detection device D, which includes a circuit control module 1 and an electrical detection module 2. Comparing FIG. 8 to FIG. 10 with FIG. 3 to FIG. 5 respectively, the main difference between the second embodiment and the first embodiment is as follows: in the second embodiment, each electrical connection structure 23 may at least include two conductive through layers 231 passing through a corresponding one of the movable carrying substrates 21 (i.e., the plurality of conductive connection layers 232 of the first embodiment can be omitted), each conductive through layer 231 has a top conductive contact 2310 disposed on a top side thereof, and a bottom side of each conductive through layer 231 can directly and electrically contact the corresponding electrical detection structure 22.

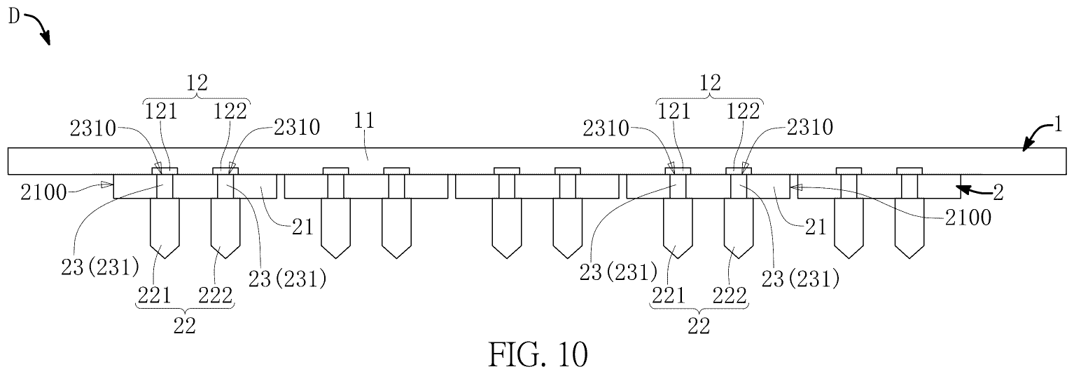

More particularly, as shown in FIG. 10, the bottom side of each conductive through layer 231 can directly and electrically contact the corresponding electrical detection structure 22, so that the first electrical detection probe 221 can be electrically connected to the circuit control module 1 through a corresponding one of the conductive through layers 231, and a corresponding one of the first conduction contacts 121 in sequence, and the second electrical detection probe 222 can be electrically connected to the circuit control module 1 through another corresponding one of the conductive through layers 231 and another corresponding one of the second conduction contacts 122 in sequence. For example, in one of the feasible embodiments, the first electrical detection probe 221 and the conductive through layer 231 of the electrical connection structure 23 corresponding to the electrical detection structure 22 that are electrically connected to each other can be a one-piece conductive structure or a non-integrated conductive structure, and the second electrical detection probe 222 of the electrical detection structure 22 and the conductive through layer 231 of the electrical connection structure 23 that are electrically connected to each other can be a one-piece conductive structure or a non-integrated conductive structure. However, the aforementioned details are disclosed for exemplary purposes only, and are not meant to limit the scope of the present disclosure.

Therefore, the same as the first embodiment, as shown in FIG. 10, the movable carrying substrates 21 can be separately disposed on a bottom side of the flexible circuit substrate 11 by cutting or removing material, so that each movable carrying substrate 21 can be configured to be allowed to be slightly adjusted through the flexible bearing of the flexible circuit substrate 11, thereby allowing each electrical detection structure 22 to be configured to be slightly adjusted following the corresponding movable carrying substrate 21.

Furthermore, each electrical detection structure 22 can be configured to be slightly adjusted following the corresponding movable carrying substrate 21, so that the first electrical detection probe 221 and the second electrical detection probe 222 of each electrical detection structure 22 can reliably electrically contact two conductive pads (not shown) of a corresponding one of the chips (not shown) to be detected respectively.

### Third Embodiment

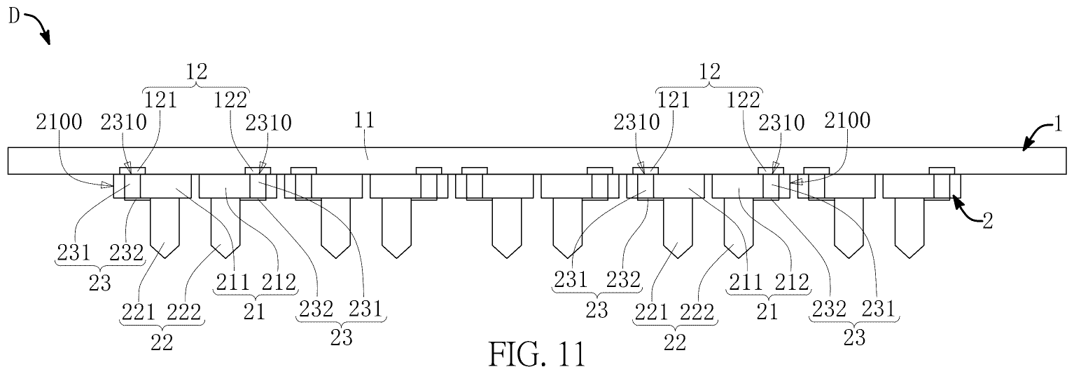

Referring to FIG. 11, a third embodiment of the present disclosure provides a chip electrical property detection device D, which includes a circuit control module 1 and an electrical detection module 2. Comparing FIG. 11 with FIG. 5, the main difference between the third embodiment and the first embodiment is as follows: in the third embodiment, each movable carrying substrate 21 further includes a first movable carrying plate 211 (in which the outer surrounding surface of the first movable carrying plate 211 may be a surrounding cut surface or a surrounding roughened surface formed by cutting or material removal) and a second movable carrying plate 212 (in which the outer surrounding surface of the second movable carrying plate 212 may be a surrounding cut surface or a surrounding roughened surface formed by cutting or material removal) that can be separated from each other by cutting or removing material (or by a cutting step or a material removal step), and the first electrical detection probe 221 and the second electrical detection probe 222 of each electrical detection structure 22 can be respectively disposed on the first movable carrying plate 211 and the second movable carrying plate 212 of the corresponding movable carrying substrate 21.

Therefore, as shown in FIG. 11, the first movable carrying plate 211 and the second movable carrying plate 212 of the movable carrying substrates 21 can be separately disposed on a bottom side of the flexible circuit substrate 11, so that the first movable carrying plate 211 and the second movable carrying plate 212 of each movable carrying substrate 21 can be configured to be allowed to be slightly adjusted through the flexible bearing of the flexible circuit substrate 11, thereby allowing the first electrical detection probe 221 and the second electrical detection probe 222 of each electrical detection structure 22 to be respectively configured to be slightly adjusted following the first movable carrying plate 211 and the second movable carrying plate 212 of the corresponding movable carrying substrate 21. Furthermore, the first electrical detection probe 221 and the second electrical detection probe 222 of each electrical detection structure 22 can be respectively configured to be slightly adjusted following the first movable carrying plate 211 and the second movable carrying plate 212 of the corresponding movable carrying substrate 21, so that the first electrical detection probe 221 and the second electrical detection probe 222 of each electrical detection structure 22 can reliably electrically contact two conductive pads (not shown) of a corresponding one of the chips (not shown) to be detected respectively.

### Fourth Embodiment

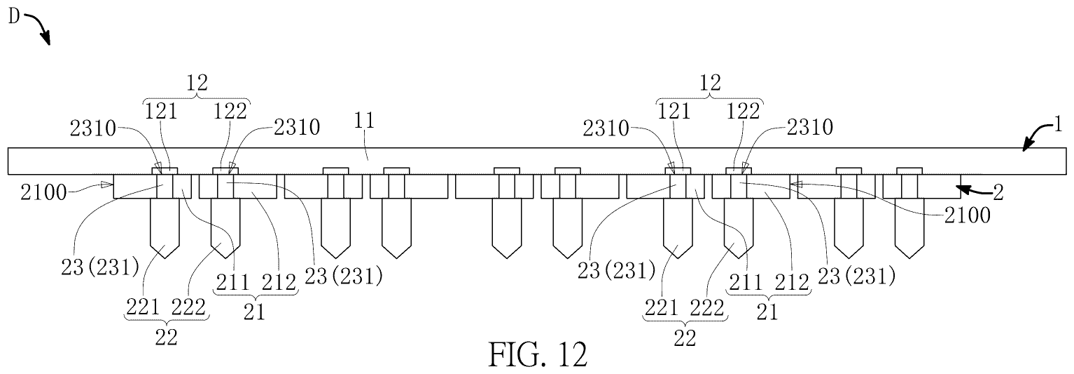

Referring to FIG. 12, a fourth embodiment of the present disclosure provides a chip electrical property detection device D, which includes a circuit control module 1 and an electrical detection module 2. Comparing FIG. 12 with FIG. 10, the main difference between the fourth embodiment and the second embodiment is as follows: in the fourth embodiment, each movable carrying substrate 21 further includes a first movable carrying plate 211 (in which the outer surrounding surface of the first movable carrying plate 211 may be a surrounding cut surface or a surrounding roughened surface formed by cutting or material removal) and a second movable carrying plate 212 (in which the outer surrounding surface of the second movable carrying plate 212 may be a surrounding cut surface or a surrounding roughened surface formed by cutting or material removal) that can be separated from each other by cutting or removing material (or by a cutting step or a material removal step), and the first electrical detection probe 221 and the second electrical detection probe 222 of each electrical detection structure 22 can be respectively disposed on the first movable carrying plate 211 and the second movable carrying plate 212 of the corresponding movable carrying substrate 21.

Therefore, as shown in FIG. 12, the first movable carrying plate 211 and the second movable carrying plate 212 of the movable carrying substrates 21 can be separately disposed on a bottom side of the flexible circuit substrate 11, so that the first movable carrying plate 211 and the second movable carrying plate 212 of each movable carrying substrate 21 can be configured to be allowed to be slightly adjusted through the flexible bearing of the flexible circuit substrate 11, thereby allowing the first electrical detection probe 221 and the second electrical detection probe 222 of each electrical detection structure 22 to be respectively configured to be slightly adjusted following the first movable carrying plate 211 and the second movable carrying plate 212 of the corresponding movable carrying substrate 21. Furthermore, the first electrical detection probe 221 and the second electrical detection probe 222 of each electrical detection structure 22 can be respectively configured to be slightly adjusted following the first movable carrying plate 211 and the second movable carrying plate 212 of the corresponding movable carrying substrate 21, so that the first electrical detection probe 221 and the second electrical detection probe 222 of each electrical detection structure 22 can reliably electrically contact two conductive pads (not shown) of a corresponding one of the chips (not shown) to be detected respectively.

### Beneficial Effects of the Embodiments

In conclusion, in the chip electrical property detection device D provided by the present disclosure, by virtue of “the circuit control module 1 including a flexible circuit substrate 11 and a plurality of electrical conduction structures 12,” “the electrical detection module 2 including a plurality of movable carrying substrates 21, a plurality of electrical detection structures 22 and a plurality of electrical connection structures 23,” “the movable carrying substrates 21 being separate from each other and disposed on the flexible circuit substrate 11,” “the electrical detection structures 22 being respectively disposed on the movable carrying substrates 21 and electrically connected to the electrical connection structures 23” and “the electrical connection structures 23 respectively passing through the movable carrying substrates 21 and respectively and electrically connecting to the electrical conduction structures 12,” each movable carrying substrate 21 can be configured to be allowed to be slightly adjusted through the flexible bearing of the flexible circuit substrate 11, thereby allowing each electrical detection structure 22 to be configured to be slightly adjusted following the corresponding movable carrying substrate 21.

Furthermore, in the method of manufacturing the chip electrical property detection device D provided by the present disclosure, by virtue of “providing a circuit control module 1, in which the circuit control module 1 includes a flexible circuit substrate 11 and a plurality of electrical conduction structures 12,” “providing an electrical detection module 2, in which the electrical detection module 2 includes a plurality of movable carrying substrates 21, a plurality of electrical detection structures 22 and a plurality of electrical connection structures 23,” “cooperating the circuit control module 1 and the electrical detection module 2 with each other to form the chip electrical property detection device D,” “the movable carrying substrates 21 being separate from each other and disposed on the flexible circuit substrate 11,” “the electrical detection structures 22 being respectively disposed on the movable carrying substrates 21 and electrically connected to the electrical connection structures 23” and “the electrical connection structures 23 respectively passing through the movable carrying substrates 21 and respectively and electrically connecting to the electrical conduction structures 12,” each movable carrying substrate 21 can be configured to be allowed to be slightly adjusted through the flexible bearing of the flexible circuit substrate 11, thereby allowing each electrical detection structure 22 to be configured to be slightly adjusted following the corresponding movable carrying substrate 21.

The foregoing description of the exemplary embodiments of the disclosure has been presented only for the purposes of illustration and description and is not intended to be exhaustive or to limit the disclosure to the precise forms disclosed. Many modifications and variations are possible in light of the above teaching.

The embodiments were chosen and described in order to explain the principles of the disclosure and their practical application so as to enable others skilled in the art to utilize the disclosure and various embodiments and with various modifications as are suited to the particular use contemplated. Alternative embodiments will become apparent to those skilled in the art to which the present disclosure pertains without departing from its spirit and scope.

What is claimed is:

1. A chip electrical property detection device, comprising:
a circuit control module including a flexible circuit substrate and a plurality of electrical conduction structures; and
an electrical detection module including a plurality of movable carrying substrates, a plurality of electrical detection structures and a plurality of electrical connection structures;
wherein the circuit control module and the electrical detection module are configured to cooperate with each other to form the chip electrical property detection device;
wherein the flexible circuit substrate has a predetermined circuit layout, and the electrical conduction structures are disposed on the flexible circuit substrate and electrically connected to the predetermined circuit layout of the flexible circuit substrate;
wherein the movable carrying substrates are separate from each other and disposed on the flexible circuit substrate, the electrical detection structures are respectively disposed on the movable carrying substrates and electrically connected to the electrical connection structures, and the electrical connection structures respectively pass through the movable carrying substrates and are respectively and electrically connected to the electrical conduction structures.

2. The chip electrical property detection device according to claim 1,
wherein each of the electrical connection structures includes two conductive through layers passing through a corresponding one of the movable carrying substrates, and two conductive connection layers disposed on a bottom side of the corresponding movable carrying substrate, each of the conductive through layers has a top conductive contact disposed on a top side thereof, and a bottom side of each of the conductive through layers is electrically connected to one of the conductive connection layers;
wherein two adjacent ones of the movable carrying substrates are separate from each other by a predetermined distance, and an outer surrounding surface of each of the movable carrying substrates is a surrounding cutting surface formed by cutting;
wherein each of the electrical conduction structures of the circuit control module includes a first conduction contact and a second conduction contact adjacent to each other, and each of the electrical detection structures includes a first electrical detection probe and a second electrical detection probe, the first electrical detection probe is electrically connected to the circuit control module through a corresponding one of the conductive connection layers, a corresponding one of the conductive through layers, and a corresponding one of the first conduction contacts in sequence, and the second electrical detection probe is electrically connected to the circuit control module through another corresponding one of the conductive connection layers, another corresponding one of the conductive through layers and another corresponding one of the second conduction contacts in sequence;
wherein the movable carrying substrates are separately disposed on a bottom side of the flexible circuit substrate, and each of the movable carrying substrates is configured to be allowed to be slightly adjusted through the flexible circuit substrate, thereby allowing each of the electrical detection structures to be configured to be slightly adjusted following the corresponding movable carrying substrate.

3. The chip electrical property detection device according to claim 2,
wherein the first conduction contact and the second conduction contact of each of the electrical conduction structures are electrically connected to the flexible circuit substrate;
wherein the flexible circuit substrate of the circuit control module is configured to carry a plurality of functional chips, and each of the functional chips is electrically connected to a corresponding one of the electrical detection structures through a corresponding one of the electrical conduction structures and a corresponding one of the electrical connection structures;
wherein the flexible circuit substrate is configured as a polyimide flexible circuit board, a modified polyimide flexible circuit board, a polyester flexible circuit board or a liquid crystal polymer flexible circuit board;
wherein the movable carrying substrate is configured as a silicon wafer substrate;
wherein, when the chip electrical property detection device is configured to detect a plurality of chips, the chip electrical property detection device is configured to be moved downward through a downward pressure provided by a flexible pressing device, so that the first electrical detection probe and the second electrical detection probe of each of the electrical detection structures respectively and electrically contact two conductive pads of a corresponding one of the chips;
wherein each of the movable carrying substrates includes a first movable carrying plate and a second movable carrying plate that are separate from each other, and the first electrical detection probe and the second electrical detection probe of each of the electrical detection structures are respectively disposed on the first movable carrying plate and the second movable carrying plate of the corresponding movable carrying substrate.

4. The chip electrical property detection device according to claim 1,
wherein each of the electrical connection structures includes two conductive through layers passing through a corresponding one of the movable carrying substrates, each of the conductive through layers has a top conductive contact disposed on a top side thereof, and a bottom side of each of the conductive through layers electrically contacts the corresponding electrical detection structure;
wherein two adjacent ones of the movable carrying substrates are separate from each other by a predetermined distance, and an outer surrounding surface of each of the movable carrying substrates is a surrounding cutting surface formed by cutting;
wherein each of the electrical conduction structures of the circuit control module includes a first conduction contact and a second conduction contact adjacent to each other, and each of the electrical detection structures includes a first electrical detection probe and a second electrical detection probe, the first electrical detection probe is electrically connected to the circuit control module through a corresponding one of the conductive through layers, and a corresponding one of the first conduction contacts in sequence, and the second electrical detection probe is electrically connected to the circuit control module through another corresponding one of the conductive through layers and another corresponding one of the second conduction contacts in sequence;
wherein the movable carrying substrates are separately disposed on a bottom side of the flexible circuit substrate, and each of the movable carrying substrates is configured to be allowed to be slightly adjusted through the flexible circuit substrate, thereby allowing each of the electrical detection structures to be configured to be slightly adjusted following the corresponding movable carrying substrate.

5. The chip electrical property detection device according to claim 4,
wherein the first conduction contact and the second conduction contact of each of the electrical conduction structures are electrically connected to the flexible circuit substrate;
wherein the flexible circuit substrate of the circuit control module is configured to carry a plurality of functional chips, and each of the functional chips is electrically connected to a corresponding one of the electrical detection structures through a corresponding one of the electrical conduction structures and a corresponding one of the electrical connection structures;
wherein the flexible circuit substrate is configured as a polyimide flexible circuit board, a modified polyimide flexible circuit board, a polyester flexible circuit board or a liquid crystal polymer flexible circuit board;
wherein the movable carrying substrate is configured as a silicon wafer substrate;
wherein, when the chip electrical property detection device is configured to detect a plurality of chips, the chip electrical property detection device is configured to be moved downward through a downward pressure provided by a flexible pressing device, so that the first electrical detection probe and the second electrical detection probe of each of the electrical detection structures respectively and electrically contact two conductive pads of a corresponding one of the chips;
wherein each of the movable carrying substrates includes a first movable carrying plate and a second movable carrying plate that are separate from each other, and the first electrical detection probe and the second electrical detection probe of each of the electrical detection structures are respectively disposed on the first movable carrying plate and the second movable carrying plate of the corresponding movable carrying substrate.

6. A method of manufacturing a chip electrical property detection device, comprising:
providing a circuit control module, wherein the circuit control module includes a flexible circuit substrate and a plurality of electrical conduction structures;
providing an electrical detection module, wherein the electrical detection module includes a plurality of movable carrying substrates, a plurality of electrical detection structures and a plurality of electrical connection structures; and
cooperating the circuit control module and the electrical detection module with each other to form the chip electrical property detection device;
wherein the flexible circuit substrate has a predetermined circuit layout, and the electrical conduction structures are disposed on the flexible circuit substrate and electrically connected to the predetermined circuit layout of the flexible circuit substrate;
wherein the movable carrying substrates are separate from each other and disposed on the flexible circuit substrate, the electrical detection structures are respectively disposed on the movable carrying substrates and electrically connected to the electrical connection structures, and the electrical connection structures respectively pass through the movable carrying substrates and are respectively and electrically connected to the electrical conduction structures.

7. The method according to claim 6,
wherein each of the electrical connection structures includes two conductive through layers passing through a corresponding one of the movable carrying substrates, and two conductive connection layers disposed on a bottom side of the corresponding movable carrying substrate, each of the conductive through layers has a top conductive contact disposed on a top side thereof, and a bottom side of each of the conductive through layers is electrically connected to one of the conductive connection layers;
wherein two adjacent ones of the movable carrying substrates are separate from each other by a predetermined distance, and an outer surrounding surface of each of the movable carrying substrates is a surrounding cutting surface formed by cutting;
wherein each of the electrical conduction structures of the circuit control module includes a first conduction contact and a second conduction contact adjacent to each other, and each of the electrical detection structures includes a first electrical detection probe and a second electrical detection probe, the first electrical detection probe is electrically connected to the circuit control module through a corresponding one of the conductive connection layers, a corresponding one of the conductive through layers, and a corresponding one of the first conduction contacts in sequence, and the second electrical detection probe is electrically connected to the circuit control module through another corresponding one of the conductive connection layers, another corresponding one of the conductive through layers and another corresponding one of the second conduction contacts in sequence;
wherein the movable carrying substrates are separately disposed on a bottom side of the flexible circuit substrate by cutting or removing material, and each of the movable carrying substrates is configured to be allowed to be slightly adjusted through the flexible circuit substrate, thereby allowing each of the electrical detection structures to be configured to be slightly adjusted following the corresponding movable carrying substrate.

8. The method according to claim 7,
wherein the first conduction contact and the second conduction contact of each of the electrical conduction structures are electrically connected to the flexible circuit substrate;
wherein the flexible circuit substrate of the circuit control module is configured to carry a plurality of functional chips, and each of the functional chips is electrically connected to a corresponding one of the electrical detection structures through a corresponding one of the electrical conduction structures and a corresponding one of the electrical connection structures;
wherein the flexible circuit substrate is configured as a polyimide flexible circuit board, a modified polyimide flexible circuit board, a polyester flexible circuit board or a liquid crystal polymer flexible circuit board;
wherein the movable carrying substrate is configured as a silicon wafer substrate;
wherein, when the chip electrical property detection device is configured to detect a plurality of chips, the chip electrical property detection device is configured to be moved downward through a downward pressure provided by a flexible pressing device, so that the first electrical detection probe and the second electrical detection probe of each of the electrical detection structures respectively and electrically contact two conductive pads of a corresponding one of the chips;
wherein each of the movable carrying substrates includes a first movable carrying plate and a second movable carrying plate that are separate from each other by cutting or removing material, and the first electrical detection probe and the second electrical detection probe of each of the electrical detection structures are respectively disposed on the first movable carrying plate and the second movable carrying plate of the corresponding movable carrying substrate.

9. The method according to claim 6,
wherein each of the electrical connection structures includes two conductive through layers passing through a corresponding one of the movable carrying substrates, each of the conductive through layers has a top conductive contact disposed on a top side thereof, and a bottom side of each of the conductive through layers electrically contacts the corresponding electrical detection structure;
wherein two adjacent ones of the movable carrying substrates are separate from each other by a predetermined distance, and an outer surrounding surface of each of the movable carrying substrates is a surrounding cutting surface formed by cutting;
wherein each of the electrical conduction structures of the circuit control module includes a first conduction contact and a second conduction contact adjacent to each other, and each of the electrical detection structures includes a first electrical detection probe and a second electrical detection probe, the first electrical detection probe is electrically connected to the circuit control module through a corresponding one of the conductive through layers, and a corresponding one of the first conduction contacts in sequence, and the second electrical detection probe is electrically connected to the circuit control module through another corresponding one of the conductive through layers and another corresponding one of the second conduction contacts in sequence;
wherein the movable carrying substrates are separately disposed on a bottom side of the flexible circuit substrate by cutting or removing material, and each of the movable carrying substrates is configured to be allowed to be slightly adjusted through the flexible circuit substrate, thereby allowing each of the electrical detection structures to be configured to be slightly adjusted following the corresponding movable carrying substrate.

10. The method according to claim 9,
wherein the first conduction contact and the second conduction contact of each of the electrical conduction structures are electrically connected to the flexible circuit substrate;
wherein the flexible circuit substrate of the circuit control module is configured to carry a plurality of functional chips, and each of the functional chips is electrically connected to a corresponding one of the electrical detection structures through a corresponding one of the electrical conduction structures and a corresponding one of the electrical connection structures;
wherein the flexible circuit substrate is configured as a polyimide flexible circuit board, a modified polyimide flexible circuit board, a polyester flexible circuit board or a liquid crystal polymer flexible circuit board;
wherein the movable carrying substrate is configured as a silicon wafer substrate;
wherein, when the chip electrical property detection device is configured to detect a plurality of chips, the chip electrical property detection device is configured to be moved downward through a downward pressure provided by a flexible pressing device, so that the first electrical detection probe and the second electrical detection probe of each of the electrical detection structures respectively and electrically contact two conductive pads of a corresponding one of the chips;
wherein each of the movable carrying substrates includes a first movable carrying plate and a second movable carrying plate that are separate from each other by cutting or removing material, and the first electrical detection probe and the second electrical detection probe of each of the electrical detection structures are respectively disposed on the first movable carrying plate and the second movable carrying plate of the corresponding movable carrying substrate.
